(19) United States
(12) Patent Application Publication
(10) Pub. No.: US 2025/0221268 A1
(43) Pub. Date: Jul. 3, 2025

(54) DISPLAY DEVICE

(71) Applicant: Japan Display Inc., Tokyo (JP)

(72) Inventors: Tomohiko NAGANUMA, Tokyo (JP); Junko NAGASAWA, Tokyo (JP)

(73) Assignee: Japan Display Inc., Tokyo (JP)

(21) Appl. No.: 19/003,093

(22) Filed: Dec. 27, 2024

(30) Foreign Application Priority Data
Dec. 27, 2023 (JP) 2023-220914

(51) Int. Cl. H10K 59/80; H10K 59/122

(52) U.S. Cl. CPC H10K 59/873; H10K 59/122; H10K 59/879

(57) ABSTRACT

According to one embodiment, a display device includes an insulating substrate, an organic electroluminescence element located on the insulating substrate and including an anode electrode and an organic light emitting layer, a rib located on the insulating substrate and including an anode aperture in a position that overlaps the anode electrode, a sealing layer that seals the organic electroluminescence element and the rib between the insulating substrate and itself, a first lens located on the sealing layer, and an overcoat layer which covers the first lens, and the first lens overlaps the anode aperture, an edge of the anode aperture, and the rib, thereacross.

### CROSS-REFERENCE TO RELATED APPLICATIONS

This application is based upon and claims the benefit of priority from Japanese Patent Application No. 2023-220914, filed Dec. 27, 2023, the entire contents of which are incorporated herein by reference.

### FIELD

Embodiments described herein relate generally to a display device.

### BACKGROUND

In recent years, organic EL element OLED display devices that in which organic light emitting diodes (OLEDs) are applied as display elements have been put to practical use. Such display devices comprise an anode electrode, a cathode electrode opposing the anode electrode, and an organic light emitting layer located between the anode electrode and the cathode electrode.

Organic EL display devices such as described above require technology for efficiently extracting the light generated in the organic light-emitting layer to the outside. For example, there is a known technology that in which micro-lens arrays containing a plurality of micro-lenses are combined in order to improve the brightness of the organic EL display device.

### BRIEF DESCRIPTION OF THE DRAWINGS

FIG. 1 is a plan view schematically showing a display device according to an embodiment.

FIG. 2 is a plan view showing a pixel of a display panel shown in FIG. 1.

FIG. 3 is a cross-sectional view showing the display panel taken along line A-B shown in FIG. 2.

FIG. 4 is a cross-sectional view illustrating refraction of light in a lens.

FIG. 5A is a diagram showing results of optical simulations when the arrangement and diameter of the lens relative to an anode aperture are changed.

FIG. 5B is a diagram showing results of optical simulations when the arrangement and diameter of the lens relative to an anode aperture are changed.

FIG. 5C is a diagram showing results of optical simulations when the arrangement and diameter of the lens relative to an anode aperture are changed.

FIG. 5D is a diagram showing results of optical simulations when the arrangement and diameter of the lens relative to an anode aperture are changed.

FIG. 5E is a diagram showing results of optical simulations when the arrangement and diameter of the lens relative to an anode aperture are changed.

FIG. 5F is a diagram showing results of optical simulations when the arrangement and diameter of the lens relative to an anode aperture are changed.

FIG. 6 is a graph showing the relationship between a viewing angle and a luminance ratio when the thickness of the lens is changed.

FIG. 7 is a graph showing the relationship between the viewing angle and the luminance ratio when the thickness of the lens is changed by reducing the refractive index of the lens by 0.1.

FIG. 8 is a cross-sectional view showing the first modified example of the display panel.

FIG. 9 is a plan view showing the second modified example of the display panel.

FIG. 10 is a cross-sectional view showing the third modified example of the display panel.

### DETAILED DESCRIPTION

In general, according to one embodiment, a display device comprises
an insulating substrate;
an organic electroluminescence element located on the insulating substrate and comprising an anode electrode and an organic light emitting layer;
a rib located on the insulating substrate and including an anode aperture in a position that overlaps the anode electrode;
a sealing layer that seals the organic electroluminescence element and the rib between the insulating substrate and itself;
a first lens located on the sealing layer; and
an overcoat layer which covers the first lens, wherein
the first lens overlaps the anode aperture, an edge of the anode aperture, and the rib, thereacross.

Embodiments will be described hereinafter with reference to the accompanying drawings. Note that the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

### First Embodiment

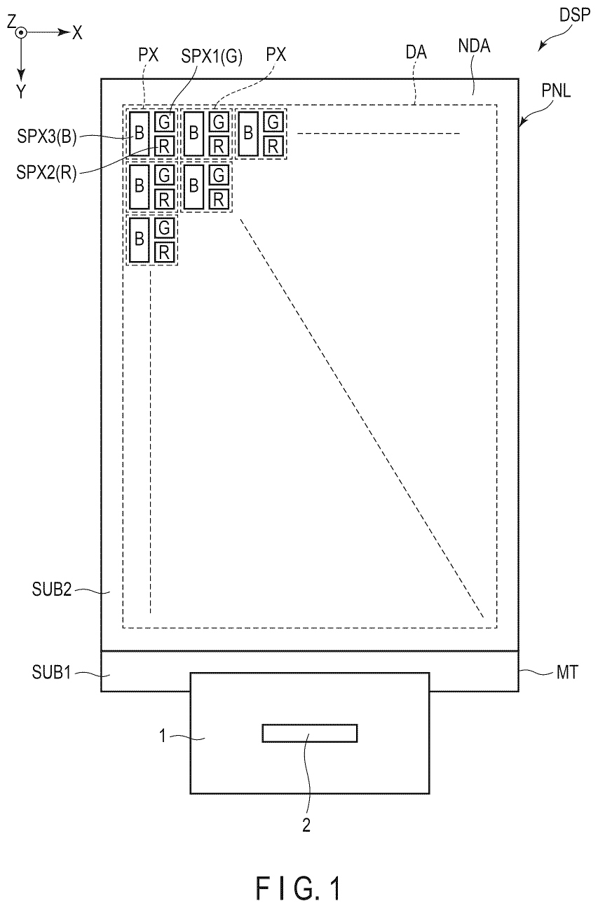

First, a configuration of the first embodiment will be described with reference to FIGS. 1 to 4.

FIG. 1 is a plan view schematically showing a display device according to an embodiment. The display device of this embodiment is an organic electroluminescence (EL) display device.

For example, a first direction X, a second direction Y and a third direction Z are orthogonal to each other, but may intersect at an angle other than 90°. The first direction X and the second direction Y correspond to directions parallel to a main surface of a substrate that constitutes the display device DSP. The third direction Z corresponds to a thickness direction of the display device DSP. In this specification, the direction toward the tip of the arrow in the third direction Z is defined as up, and the direction opposite to the direction toward the tip of the arrow in the third direction Z is defined as down. Further, it is assumed that there is an observation position to observe the display device DSP on a tip side of the arrow in the third direction Z. Here, viewing from this observation position toward the X-Y plane defined by the first direction X and the second direction Y is referred to as plan view.

The display device DSP comprises a display panel PNL and a wiring substrate 1 mounted on the display panel PNL.

The display panel PNL is an organic EL display panel and comprises a first substrate SUB1 and a second substrate SUB2 disposed to oppose the first substrate SUB1. The first substrate SUB1 includes a mount portion MT exposed to an outer side further from the second substrate SUB2. The display panel PNL comprises a display area DA which displays images and a non-display area NDA which surrounds the display area DA. The display panel PNL comprises a plurality of pixels PX arranged in a matrix along the first direction X and the second direction Y in the display area DA.

The pixels PX are each constituted by a subpixel SPX1 that displays green color (G), a subpixel SPX2 that displays color red (R), and a subpixel SPX3 that displays blue color (B). In each pixel PX, the subpixel SPX3 extends along the second direction Y. The subpixel SPX1 is aligned with the subpixel SPX3 along the first direction X. The subpixel SPX2 is aligned with the subpixel SPX3 along the first direction X and also aligned with the subpixel SPX1 along the second direction Y.

Note that the size, arrangement, and color of each subpixel are not limited to those of the example illustrated here. Further, in the example illustrated, the pixels PX having the identical subpixel pattern are aligned in a matrix, but the configuration is not limited to this. The size, arrangement, and color of subpixels may be different from one pixel PX to another.

The wiring substrate 1 is a flexible substrate and is mounted on the mount portion MT. The display panel PNL and the wiring substrate 1 are electrically connected to each other. The wiring substrate 1 comprises a drive IC chip 2 that drives the display panel PNL. Note that the drive IC chip 2 may be mounted on the mount portion MT.

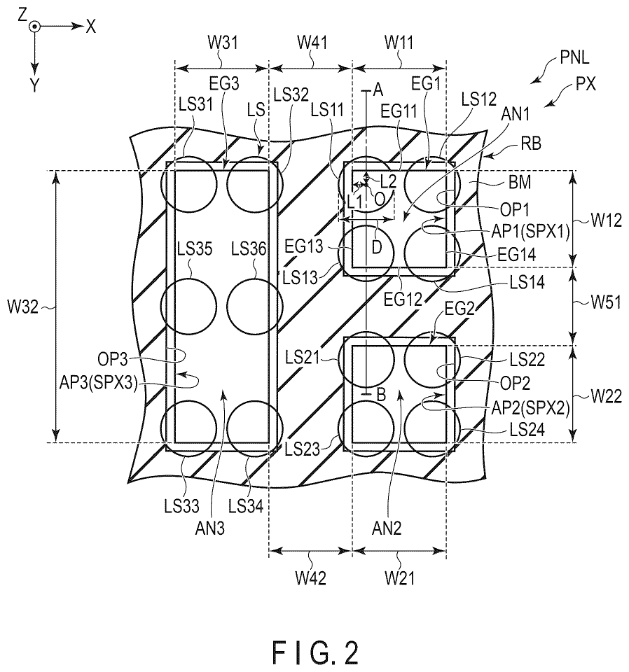

FIG. 2 is a plan view showing one pixel PX of the display panel PNL shown in FIG. 1.

The display panel PNL comprises an anode electrode AN1, an anode electrode AN2, and an anode electrode AN3, a rib RB, a light-shielding layer BM, and a plurality of lenses LS.

The anode electrode AN1, the anode electrode AN2, and the anode electrode AN3 are disposed in the subpixel SPX1, the subpixel SPX2, and the subpixel SPX3, respectively.

The rib RB includes an anode aperture AP1 that defines the subpixel SPX1, an anode aperture AP2 that defines the subpixel SPX2, and an anode aperture AP3 that defines the subpixel SPX3. The arrangement of the anode apertures AP1 to AP3 is similar to the arrangement of the subpixels SPX1 to SPX3. The anode apertures AP1 to AP3 are each formed into a rectangular shape.

The anode aperture AP1 is formed at a position that overlaps the anode electrode AN1. The anode aperture AP2 is formed at a position that overlaps the anode electrode AN2. The anode aperture AP3 is formed at a position that overlaps the anode electrode AN3.

The anode aperture AP1 includes an edge EG1, which is an outer periphery of the anode aperture AP1. The edge EG1 includes an edge EG11 and an edge EG12, which extend in the first direction X, and an edge EG13 and an edge EG14, which extend in the second direction Y. Further, the anode aperture AP2 includes an edge EG2, which is an outer periphery of the anode aperture AP2. The anode aperture AP3 includes an edge EG3, which is an outer periphery of the anode aperture AP3.

The anode aperture AP1 has a width W11 along the first direction X, which is about 20 μm. The anode aperture AP1 has a width W12 along the second direction Y, which is about 20 μm. The anode aperture AP2 has a width W21 along the first direction X, which is about 20 μm. The anode aperture AP2 has a width W22 along the second direction Y, which is about 20 μm. The anode aperture AP3 has a width W31 along the first direction X, which is about 20 μm. The anode aperture AP3 has a width W32 along the second direction Y, which is about 60 μm.

Between the anode aperture AP1 and the anode aperture AP3, there is a gap having a width W41 along the first direction X, which is about 20 μm. Between the anode aperture AP2 and the anode aperture AP3, there is a gap having a width W42 along the first direction X, which is about 20 μm. Between the anode aperture AP1 and the anode aperture AP2, there is a gap having a width W51 along the second direction Y, which is about 20 μm. The width W41, the width W42, and the width W51 correspond to the width of the rib RB.

The light-shielding layer BM is disposed on the area indicated by the diagonal lines in the drawing. The light-shielding layer BM overlaps the rib RB in the entire area indicated by the diagonal lines in the drawing. The light-shielding layer BM has an aperture OP1, an aperture OP2, and an aperture OP3. The aperture OP1 is formed at a position that overlaps the anode aperture AP1. The aperture OP2 is formed at a position that overlaps the anode aperture AP2. The aperture OP3 is formed at a position that overlaps the anode aperture AP3.

The aperture OP1 has a width along the first direction X, which is greater than the width W11 of anode aperture AP1 along the first direction X. The aperture OP1 has a width along the second direction Y, which is greater than the width W12 of the anode aperture AP1 along the second direction Y.

The aperture OP2 has a width along the first direction X, which is greater than the width W21 of the anode aperture AP2 along the first direction X. The aperture OP2 has a width along the second direction Y, which is greater than the width W22 of the anode aperture AP2 along the second direction Y.

The aperture OP3 has a width along the first direction X, which is greater than the width W31 of the anode aperture AP3 along the first direction X. The aperture OP3 has a width along the second direction Y, which is greater than the width W32 of the anode aperture AP3 along the second direction Y.

The plurality of lenses LS are formed to have sizes equal to each other and into a circularly shape in a plan view. The lenses LS each has a diameter D of, for example, about 12 μm.

In the example illustrated, four lenses LS11, LS12, LS13, and LS14 are disposed for the anode aperture AP1. The lenses LS11, LS12, LS13, and LS14 are arranged at the four corners of the anode aperture AP1, respectively. The lenses LS11, LS12, LS13, and LS14 each overlap the anode aperture AP1, the edge EG1, and the rib RB thereacross.

More specifically, the lens LS11 overlaps the anode aperture AP1, the edge EG11 and the edge EG13, and the rib RB thereacross. The lens LS12 overlaps the anode aperture AP1, the edge EG11 and the edge EG14, and the rib RB thereacross. The lens LS13 overlaps the anode aperture AP1, the edge EG12 and the edge EG13, and the rib RB thereacross. The lens LS14 overlaps the anode aperture AP1, the edge EG12 and the edge EG14, and the rib RB thereacross.

That is, the lens LS11 overlaps a connection where the edge EG11 and the edge EG13 meet each other. Similarly, the lens LS12 overlaps a connection where the edge EG11 and the edge EG14 meet each other. The lens LS13 overlaps a connection where the edges EG12 and EG13 meet each other. The lens LS14 overlaps a connection where the edges EG12 and EG14 meet each other.

In the example illustrated, four lenses LS21, LS22, LS23, and LS24 are disposed for the anode aperture AP2. The lenses LS21, LS22, LS23, and LS24 are arranged at the four corners of the anode aperture AP2, respectively. The lenses LS21, LS22, LS23, and LS24 each overlap the anode aperture AP2, the edge EG2, and the rib RB, thereacross.

In the example illustrated, there are six lenses LS31, LS32, LS33, LS34, LS35, and LS36 arranged for the anode aperture AP3. The lenses LS31, LS32, LS33, and LS34 are arranged at the four corners of the anode aperture AP3, respectively. The lenses LS35 and LS36 are positioned on long sides of the edge EG3 of the anode aperture AP3, respectively. The lens LS35 is positioned between the lens LS31 and the lens LS33. The lens LS36 is positioned between the lens LS32 and the lens LS34. The lenses LS31, LS32, LS33, LS34, LS35, and LS36 each overlap the anode aperture AP3, the edge EG3, and the rib RB, thereacross.

Note that in the example illustrated, part of each lens LS overlaps the light shielding layer BM.

With a focus on the lens LS11 in the drawing, the lens LS11 has a center O which is located on an inner side with respect to the edge EG1 of the anode aperture AP1. Similarly, the centers O of the other lenses LS are also located each on an inner side of the respective one of the edge EG1 of the anode aperture AP1, the edge EG2 of the anode aperture AP2, and the edge EG3 of the anode aperture AP3. The center 0 of the lens LS11 is located on an inner side of the edge EG13 by a length L1 in the first direction X. Further, the center O of the lens LS11 is located on an inner side of the edge EG11 by a length L2 in the second direction Y. The length L1 and the length L2 are, for example, about 3 μm.

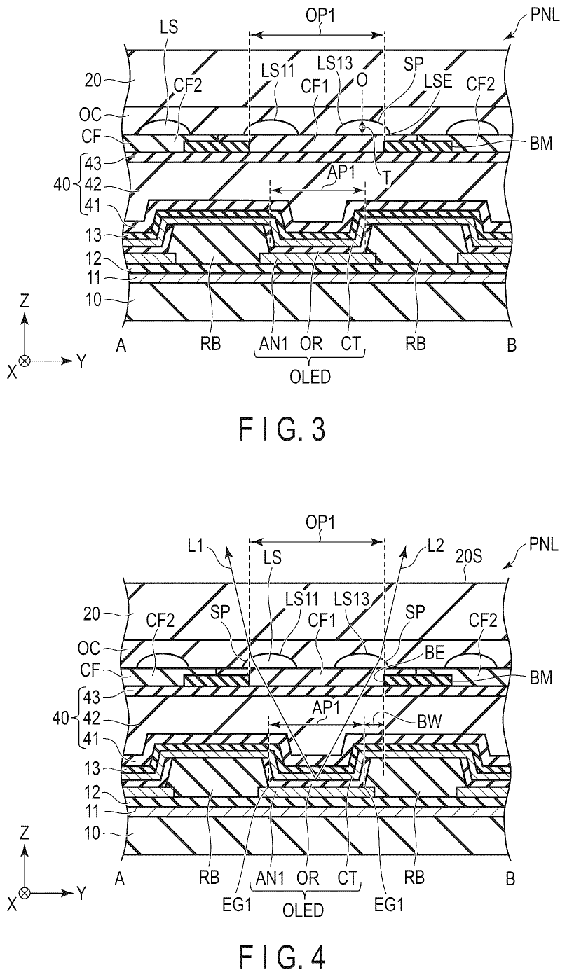

FIG. 3 is a cross-sectional view of the display panel PNL taken along the line A-B shown in FIG. 2.

As shown in FIG. 3, the display panel PNL comprises an insulating substrate 10, a circuit layer 11, an insulating film 12, an organic electroluminescence (EL) element OLED, ribs RB, a cap layer 13, a sealing layer 40, light-shielding layers BM, color filter layers CF, lenses LS, an overcoat layer OC, a sealing substrate 20, and the like.

The insulating substrate 10 may be a glass substrate or a flexible resin film.

The circuit layer 11 is formed on the insulating substrate 10. The circuit layer 11 includes various circuits such as pixel circuits and various wiring lines such as scanning lines, signal lines, and power supply lines. The insulating film 12 covers the circuit layer 11. The insulating film 12 includes an organic insulating film that planarizes the unevenness caused by the circuit layer 11.

The organic EL element OLED is formed on the insulating film 12. In other words, the organic EL element OLED is located on the insulating substrate 10. The organic EL element OLED is configured as a top emission type that radiates light towards the sealing substrate 20. One organic EL element OLED is arranged in each subpixel, and the organic EL elements OLED disposed in the subpixel SPX1, the subpixel SPX2, and the subpixel SPX3, respectively all have the same structure. The organic EL elements OLED are compartmentalized by the respective ribs RB. The ribs RB are located on the insulating substrate 10.

The anode aperture AP1 is defined by the lower end of the respective rib RB.

The organic EL element OLED comprises an anode electrode AN1. The anode electrode AN1 is electrically connected to a switching element, which is not shown in the drawing. The anode electrode AN1 is formed, for example, from a transparent conductive material such as indium tin oxide (ITO) or indium zinc oxide (IZO).

The organic EL element OLED, which is disposed in a position that overlaps the anode aperture AP1, comprises an organic light emitting layer OR that emits green light. Similarly, the organic EL element disposed in a position that overlaps the anode aperture AP2 comprises an organic light emitting layer that emits red light. The organic EL element disposed in a position that overlaps the anode aperture AP3 comprises an organic light emitting layer that emits blue light. The organic light emitting layer OR is located on top of the anode electrode AN1.

The organic EL element OLED comprises a cathode electrode CT. The cathode electrode CT is located on the organic light emitting layer OR and also commonly located on organic light emitting layers disposed in other subpixels. The cathode electrode CT is located on the respective rib RB. The cathode electrode CT is formed, for example, of a MgAg alloy.

The cap layer 13 is disposed on the cathode electrode CT. The cap layer 13 has a transparent multilayer structure. The layers that constitute the cap layer 13 have refractive indices different from each other. The cap layer 13 having such a configuration functions as an optical adjustment layer for adjusting the optical characteristics of the light emitted from the organic light emitting layer OR.

The sealing layer 40 seals the organic EL element OLED and the rib RB between the insulating substrate 10 and itself. Further, the sealing layer 40 seals other components placed between the insulating substrate 10 and itself in a similar manner. The sealing layer 40 suppresses the entering of oxygen and moisture into the organic EL element OLED, thereby suppressing the degradation of the organic EL element OLED. The sealing layer 40 is constituted by a stacked body of an inorganic film 41, an organic film 42, and an inorganic film 43. The inorganic films 41 and 43 are formed using silicon nitride, for example. The organic film 42 is formed using, for example, an organic material such as resin.

The light-shielding layer BM is located on the sealing layer 40. More specifically, the light shielding layer BM is located on the inorganic film 43 of the sealing layer 40. The aperture OP1 has a width along the second direction Y, which is, for example, about 25 μm. As described above, the width of the anode aperture AP1 along the second direction Y is about 20 μm. In other words, the width of the aperture OP1 is formed to be about 5 μm greater than the width of the anode aperture AP1. With this structure, the light that proceeds in an inclined direction from the organic EL element OLED is not blocked by the light shielding layer BM, and the visibility of the display from oblique viewing angles can be maintained.

The color filter layers CF are located on top of the light shielding layer BM and the sealing layer 40. The color filter layers CF includes a first color filter CF1 for the first color, a second color filter CF2 for a second color different from the first color, and a third color filter for a third color different from the first and second colors, which are not shown in the drawing. The first color filter CF1 overlaps the anode aperture AP1. The second color filter CF2 overlaps the anode aperture AP2. The third color filter overlaps the anode aperture AP3. The first color filter CF1 and the second color filter CF2 are adjacent to each other.

The first color filter CF1 is a green color filter. The second color filter CF2 is a red color filter. The third color filter is a blue color filter.

The first color filter CF1 overlaps the organic EL element OLED that emits green light. The second color filter CF2 overlaps the organic EL element that emits red light. The third color filter overlaps the organic EL element that emits blue light.

The colors of the first color filter CF1, second color filter CF2, and third color filter are not limited to those of the example given above, but can be changed as appropriate according to the emission color of each organic EL element.

The plurality of lenses LS are located on the color filter layers CF. In other words, the plurality of lenses LS are located on the sealing layer 40. The lens LS is formed using, for example, acrylic resin or epoxy resin. The lenses LS have a thickness T, which is, for example, about 2 um. Each of the lenses LS includes a sloping portion SP between the center 0 of the lens LS and an outer edge LSE of the lens LS. Part of the sloping portion SP overlaps the respective rib RB.

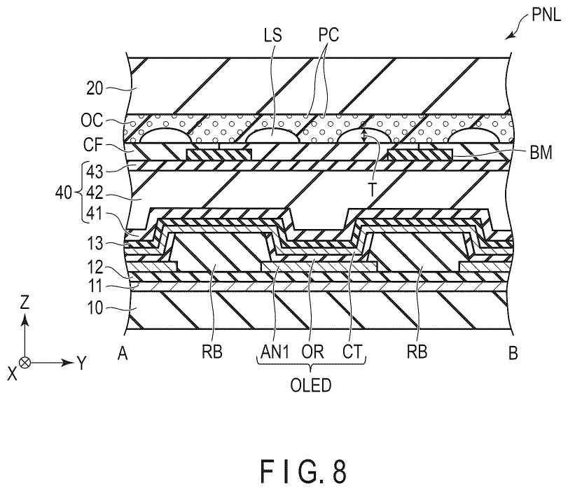

The overcoat layer OC covers the plurality of lenses LS and the color filter layers CF. The overcoat layer OC is formed from an organic material such as a transparent resin, and is formed using acrylic resin or epoxy resin. As will be described later with reference to FIG. 8, the overcoat layer OC may as well contain particles of either metal nanoparticles or hollow particles.

The sealing substrate 20 is located on top of the overcoat layer OC. The sealing substrate 20 may be a glass substrate or a flexible resin film.

The inorganic film 41 of the sealing layer 40 has a thickness of, for example, about 1 μm. The organic film 42 of the sealing layer 40 has a thickness of, for example, about 10 μm. The inorganic film 43 of the sealing layer 40 has a thickness of, for example, about 1 μm. The color filter layers CF have a thickness of, for example, about 2 μm. The overcoat layer OC has a thickness of, for example, about 4 μm. Further, the thickness of the overcoat layer OC is formed to be at least about 1 μm greater than the thickness T of the lenses LS. Since the thickness of the overcoat layer OC is 4 μm or less when it does not contain any particles, it is preferable that the thickness T of the lenses LS at this time should be 3 μm or less. The sealing substrate 20 has a thickness of, for example, about 0.5 mm.

Note that in the configuration example provided above, the display panel PNL comprises an organic light emitting layer that emits green light, an organic light emitting layer that emits red light, and an organic light emitting layer that emits blue light, but the configuration is not limited to this. For example, each organic EL element may have a common organic light-emitting layer. In such a case, for example, the organic EL element OLED emits white light. In this embodiment, the display panel PNL comprises the color filter layers CF, and therefore color display of the display device DSP can be achieved even when the organic EL element OLED emits white light.

Further, the display panel PN of this embodiment does not comprise a polarizer on the sealing substrate 20, but in place, comprises a light-shielding layer BM and a color filter layer CF on the sealing layer 40. With this structure, the color filter layers CF can suppress external light reflection at the cathode electrode CT and the like. Thus, as compared to the case where external light reflection is suppressed using polarizers, the transmittance of light emitted from the organic EL element OLED can be improved. Therefore, the decrease in display brightness can be suppressed, and the power consumption can be reduced. Further, the color filter layers CF are thin as compared to the polarizers, and therefore the display panel PNL can be made thinner. Furthermore, the cost for the case of using polarizers can be reduced.

FIG. 4 is a cross-sectional view illustrating the refraction of light in the lenses LS.

Let us assume the case where, for example, the lenses LS are not provided as a comparative example. Here, of the light that enters the interface between the sealing substrate 20 and the air at an angle from the organic EL element OLED, the light that enters at an angle greater than the critical angle is totally reflected and cannot exit from an upper surface 20S of the sealing substrate 20.

According to this embodiment, the lens LS is disposed over the edge EG1 of the anode aperture AP1. With this configuration, as shown in the drawing, light L1 emitted from the organic EL element OLED in a left diagonal direction is refracted towards the upper surface 20S at the sloping portion SP of the lens LS11, and light L2 emitted from the organic EL element OLED in a right diagonal direction is refracted towards the upper surface 20S at the sloping portion SP of the lens LS13. That is, before the light enters the interface between the sealing substrate 20 and the air, the angle of incidence of the light can be the lens LS can be reduced to a degree less than the critical angle for total reflection. Thus, the amount of light that is totally reflected is reduced, thereby making it possible to allow more light to be emitted from the upper surface 20S of the sealing substrate 20. More specifically, the lens LS can improve the brightness of the area equivalent to that extends beyond the edge EG1 of the anode aperture AP1. Therefore, the light extraction efficiency of the display panel PNL can be improved.

As described above, while the brightness of the display panel PNl can be improved by not providing a polarizer, there is a concern that the reflection of external light at the anode aperture may increase when only the color filter CF is used. From the perspective of external light reflection, it is preferable that the anode aperture ratio should be lower, that is, the coverage rate of the light-shielding layer BM need to be kept at a certain level or higher. Specifically, the area of the light shielding layer BM in a single pixel needs to be set to 65% or higher. In other words, the upper limit of the anode aperture ratio is determined by the external light reflection characteristics, which makes it difficult to improve the brightness. With the configuration of this embodiment, it is possible, even in a display device that does not have a polarizer, to improve the brightness of the display panel PNL without increasing the anode aperture ratio, that is, without increasing the external light reflection.

Next, the refractive indices of the various components that constitute the display panel PNL will be explained.

The refractive indices of the inorganic films 41 and 43 of the sealing layer 40 are, for example, 1.8. The refractive index of the organic film 42 of the sealing layer 40 is, for example, 1.6. The refractive index of the color filter layer CF is, for example, 1.6. The refractive index of the lenses LS is, for example, 1.5 to 1.7. The refractive index of the overcoat layer OC is, for example, 1.0 to 1.5. Here, when the refractive index of the overcoat layer OC is 1.0, it is assumed that hollow particles are mixed into the overcoat layer OC.

In order to refract light at the interface between the lens LS and the overcoat layer OC, the refractive index of the overcoat layer OC is set to be lower than that of the lenses LS. In order to refract light more at the interface between the lens LS and the overcoat layer OC, it is desirable that the difference between the refractive indices of the lenses LS and the overcoat layer OC should be about 0.3.

Next, the design conditions will be explained.

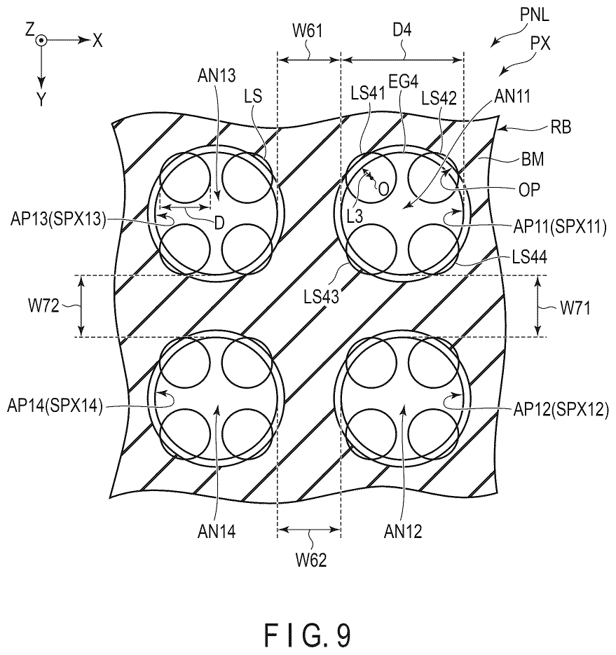

The width of the anode aperture or the diameter of the anode aperture is defined as L (μm). The width of the anode aperture is equivalent to the width of the anode aperture along the first direction X and the width of the anode aperture along the second direction Y when the anode aperture is rectangular. The diameter of the anode aperture is equivalent to the diameter of the anode aperture when the anode aperture is circular, as shown in FIG. 9.

As shown in FIG. 4, the width taken from the edge EG1 of the anode aperture AP1 to an end portion BE of the aperture OP1 of the light-shielding layer BM is defined as a one-side width BW of the aperture OP1. The one-sided width BW is independent of L (μm) and is 2.5 to 6 μm. The value of the one-sided width BW is a numerical value which ensures that light proceeding in a diagonal direction from the organic EL element OLED is not blocked by the light-shielding layer BM.

The diameter of the lenses LS is L/2±0.3 L (μm).

The center O of the lens LS is disposed on an inner side of the edge EG1 of the anode aperture AP1 by L/4±0.3 L (μm).

The thickness T of the lenses LS should preferably be L/10 to L/3 (μm).

Note that in practice, there are upper limits to the diameter and thickness of the lenses LS due to manufacturing constraints. The diameter of the lenses LS depends on the anode aperture width L. In other words, the size of the lenses LS must be greater than a certain value in relation to the size of the anode apertures. That is, because there are upper limits to the diameter and thickness of the lenses LS, there are also upper limits to the width L of the anode apertures, with which the advantageous effects of this embodiment can be obtained. The width L of the anode apertures with which the effects of this embodiment can be achieved is 110 μm or less.

The lenses LS11 and LS13 overlap the first color filter CF1 but do not overlap the second color filter CF2. In other words, each lens LS overlaps color filters of one color and does not overlap color filters of two or more colors. With this configuration, it is possible to prevent the light from being absorbed by the color filter of a different color from the adjacent emission light before the light reaches the lens LS from the organic EL element OLED, and thus prevent the decrease in light utilization efficiency.

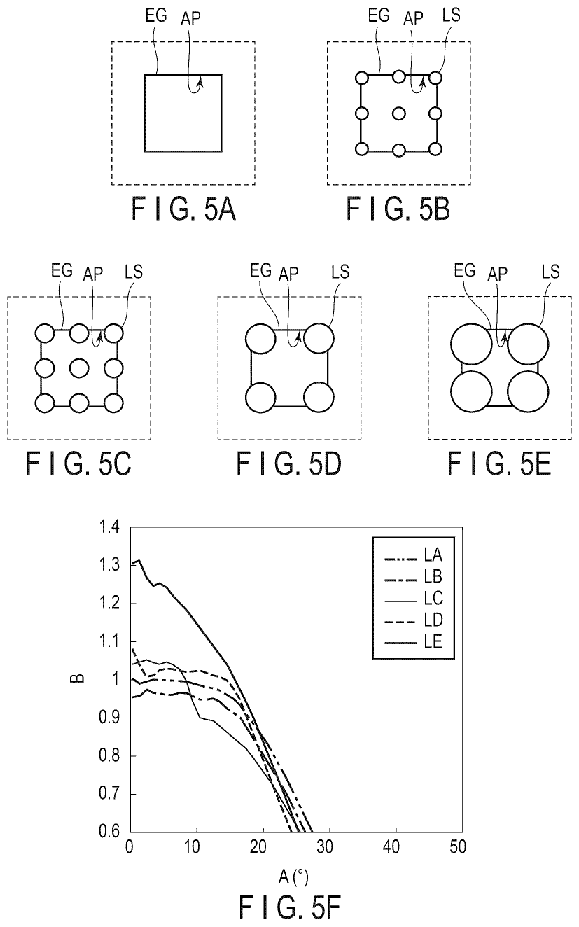

Next, the results of optical simulations will be explained with reference to FIGS. 5A to 7.

FIGS. 5A to 5F show the results of the optical simulations when the arrangement and diameter of the lenses LS relative to the anode aperture AP are varied.

The refractive index of the lens LS shown in FIGS. 5A to 5E is 1.73, and at this time, the refractive index of the overcoat layer OC is 1.46. The difference between the refractive index of the lens LS and the refractive index of the overcoat layer OC is 0.27.

FIG. 5A shows the anode aperture AP in which the lens LS is not disposed. FIG. 5A is the reference for this optical simulation. The vertical width of the anode aperture AP is 20 μm, and the horizontal width is 20 μm.

FIG. 5B shows an example in which nine lenses LS each having a diameter of 3 μm are disposed in the anode aperture AP. The lenses LS are placed at the four corners of the anode aperture AP, at the centers of the sides of the edge EG, and at the center of the anode aperture AP.

FIG. 5C shows an example in which nine lenses LS each having a diameter of 6 μm are disposed in the anode aperture AP. The lenses LS are placed at the four corners of the anode aperture AP, at the centers of the sides of the edge EG, and at the center of the anode aperture AP.

FIG. 5D shows an example in which four lenses LS each having a diameter of 9 μm are placed at the four corners of the anode aperture AP.

FIG. 5E shows an example in which four lenses LS each having a diameter of 12 μm are arranged for the anode aperture AP. The lenses LS are placed at the four corners of the anode aperture AP.

FIG. 5F is a graph showing the relationship between the viewing angle and the luminance ratio for each of the cases shown in FIG. 5A to FIG. 5E. The horizontal axis A indicates the viewing angle (°) , and the vertical axis B indicates the luminance ratio. In the graph, the line LA to line LE indicate the results for the cases of FIG. 5A to FIG. 5E, respectively.

The luminance ratio is set to 1 when the viewing angle is 0° for the line LA in the state where there is no lens LS in place. Here, a viewing angle of 0° is equivalent to an angle that is perpendicular to the display surface of the display device. Further, the luminance obtained at a viewing angle of 0° is equivalent to the luminance of the front surface of the display device.

The line LB to the line LD show no significant change compared to the reference. On the other hand, the line LE exhibited a luminance at an angle of 0° increased greatly as compared to those of the line LA to the line LD. That is, the greatest luminance increasing effect is obtained when the diameter of the lenses LS is 12 μm for the case where the width of the anode aperture AP is 20 μm. At this time, the ratio of the diameter of the lens LS to the width of the anode aperture AP is 12/20=0.6.

Under the conditions shown in FIG. 5E, a 30% increase in front-face luminance can be achieved. The total of the areas of the lenses LS that protrudes beyond the anode aperture AP is approximately 30% of the area of the anode aperture AP, and thus the results show that the parts of the lenses LS, which protrude beyond the anode aperture AP contribute to the increase in luminance.

With the optical simulations shown in FIG. 5A to FIG. 5F, such a conclusion is obtained that in order to improve the front-face luminance, the diameter of the lens LS must be a certain size or larger in relation to the width of the anode aperture AP.

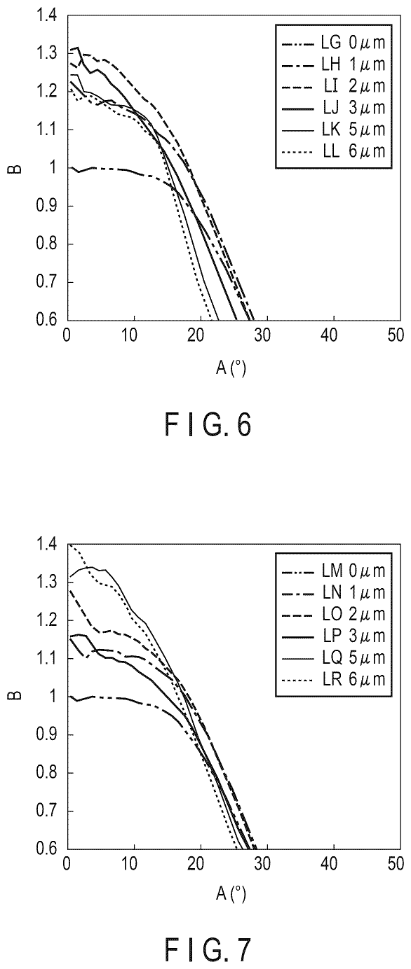

FIG. 6 shows a graph illustrating the relationship between the viewing angle and luminance ratio when the thickness of the lenses LS is varied.

The horizontal axis A indicates the viewing angle (°), and the vertical axis B indicates the luminance ratio. In the graph, the line LG, the line LH, the line LI, the line LJ, the line LK and the line LL show the results for lenses LS having thicknesses of 0 μm, 1 μm, 2 μm, 3 μm, 5 μm and 6 μm, respectively.

In the optical simulations shown in FIG. 6, the conditions for the anode aperture AP and lenses LS are fixed to the conditions indicated in FIG. 5E. That is, FIG. 6 shows the results of optical simulations in which the following conditions are applied, that is, the anode aperture AP has a vertical width of 20 μm and a horizontal width of 20 μm, and the lenses LS have a diameter of 12 μm, and four lenses LS are placed at the four corners of the anode aperture AP.

The refractive index of the lenses LS is 1.73, and the refractive index of the overcoat layer OC is 1.46. The difference between the refractive index of the lenses LS and the refractive index of the overcoat layer OC is 0.27.

The line LG shows the results for when the thickness of the lenses LS is 0 μm, that is, when the lenses LS are not in place. The line LG is the reference for the optical simulations.

The luminance ratio of the line LG is set to 1 when the viewing angle is 0° in the state where the lenses LS are not in place. The line LI and the line LJ each exhibit a large increase in luminance at a viewing angle of 0° as compared to the cases of the line LS, the line LK and the line LL. That is, the greatest luminance increasing effect is obtained when the thickness of the lenses LS is 2 μm and 3 μm.

With the optical simulations shown in FIG. 6, such a conclusion is obtained that the luminance ratio decreases below the optimum value when the thickness of the lenses LS is lower by a certain degree or higher by a certain degree.

FIG. 7 is a graph showing the relationship between the viewing angle and luminance ratio when the thickness of the lenses LS is varied by reducing the refractive index of the lens LS by 0.1.

The horizontal axis A indicates the viewing angle (°), and the vertical axis B indicates the luminance ratio. In the graph, the line LM, the line LN, the line LO, the line LP, the line LQ, and the line LR exhibit the results for the lenses LS having thicknesses of 0 μm, 1 μm, 2 μm, 3 μm, 5 μm, and 6 μm, respectively.

In the optical simulations shown in FIG. 7, the conditions for the anode aperture AP and lenses LS are fixed to the conditions shown in FIG. 5E. That is, FIG. 7 shows the results of optical simulations in which the following conditions are applied, that is, the anode aperture AP has a vertical width of 20 μm and a horizontal width of 20 μm, the lenses LS have a diameter of 12 μm, and four lenses LS are placed at the four corners of the anode aperture AP.

In the optical simulations shown in FIGS. 5A to 5F and FIG. 6, the refractive index of the lenses LS is 1.73, the refractive index of the overcoat layer OC is 1.46, and the difference between the refractive index of the lens LS and the refractive index of the overcoat layer OC is 0.27. In the optical simulations shown in FIG. 7, the refractive index of the lenses LS is reduced by 0.1, and therefore the refractive index of the lenses LS is 1.63, and the difference between the refractive index of the lens LS and the refractive index of the overcoat layer OC is 0.17.

The line LM shows the results when the thickness of the lenses LS is 0 μm, that is, when there are no lenses LS in place. The line LM is the reference for the optical simulations.

The luminance ratio for the line LM is set to 1 when the viewing angle is 0° in the state where there are no lenses LS in place. The line LQ and the line LR show a large increase in luminance at a viewing angle of 0° as compared to the cases of the line LN, the line LO, and the line LP. That is, the greatest luminance increasing effect is obtained when the thickness of the lenses LS is 5 μm and 6 μm.

With the optical simulations shown in FIG. 7, such a conclusion is obtained that, in order to increase the luminance, it is necessary to increase the thickness of the lenses LS when the refractive index of the lenses LS is decreased. In the example illustrated in FIG. 7, the difference between the refractive index of the lenses LS and the refractive index of the overcoat layer OC is smaller as compared to the case of the example illustrated in FIG. 6, and therefore light is less likely to be refracted at the interface between the lenses LS and the overcoat layer OC. Therefore, the sloping portions SP of the lenses LS need to be increased, and the thickness of the lenses LS increases. Therefore, the optimal thickness of the lenses LS depends on the refractive index of the material of the lenses LS.

### First Modification Example

Next, with reference to FIG. 8, the configuration of the first modified example will be described.

FIG. 8 is a cross-sectional view showing the first modified example of the display panel PNL.

The configuration shown in FIG. 8 is different from that shown in FIG. 3 in that the overcoat layer OC contains particles PC.

The overcoat layer OC contains particles PC of either metal nanoparticles or hollow particles.

The metal nanoparticles are, for example, nano-titanium. By mixing nano-titanium into the overcoat layer OC, the refractive index of the overcoat layer OC can be increased.

The hollow particles are, for example, of hollow silica or hollow polymer. By mixing air layers using hollow silica or hollow polymer into the overcoat layer OC, the refractive index of the overcoat layer OC can be decreased.

Further, when the thickness T of the lenses LS is increased, the thickness of the overcoat layer OC needs to be increased as well. When the overcoat layer OC is formed using only resin, it is difficult to form the overcoat layer OC to have a thickness of 4 μm or more, but by mixing the particles PC, it is possible to form the overcoat layer OC to have a thickness of 4 μm or more.

In the first modified example as well, advantageous effects similar to those described above can be obtained.

### Second Modified Example

Next, with reference to FIG. 9, the configuration of the second modified example will be explained.

FIG. 9 is a plan view showing the second modified example of the display panel PNL.

The composition shown in FIG. 9 is different from that shown in FIG. 2 mainly in that each of the anode apertures AP11, AP12, AP13, and AP14 is formed into a circular shape. FIG. 9 shows a single pixel PX of the display panel PNL.

The pixel PX is constituted by a subpixel SPX11 that displays green color, a subpixel SPX12 that displays red color, a subpixel SPX13 that displays blue color, and a subpixel SPX14 that displays green color. The subpixels SPX11 and SPX12 are aligned along the second direction Y, the subpixels SPX13 and SPX14 are aligned along the second direction Y, the subpixels SPX11 and SPX13 are aligned along the first direction X, and the subpixels SPX12 and SPX14 are aligned along the first direction X.

The size, arrangement and color of each subpixel are not limited to those specified in the example illustrated in the drawing.

The display panel PNL comprises an anode electrode AN11, an anode electrode AN12, an anode electrode AN13, an anode electrode AN14, a rib RB, a light shielding layer BM, and a plurality of lenses LS.

The anode electrodes AN11, AN12, AN13, and AN14 are disposed in the subpixels SPX11, SPX12, SPX13, and SPX14, respectively.

The rib RB includes an anode aperture AP11 that defines the subpixel SPX11, an anode aperture AP12 that defines the subpixel SPX12, an anode aperture AP13 that defines the subpixel SPX13, and an anode aperture AP14 that defines the subpixel SPX14. The arrangement of the anode apertures AP11 to AP14 is similar to the arrangement of the subpixels SPX11 to SPX14. The anode apertures AP11 to AP14 are each formed into a circular shape.

The anode aperture AP11 is formed in a position that overlaps the anode electrode AN11. The anode aperture AP12 is formed in a position that overlaps the anode electrode AN12. The anode aperture AP13 is formed in a position that overlaps the anode electrode AN13. The anode aperture AP14 is formed in a position that overlaps the anode electrode AN14. Each of the anode apertures AP11, AP12, AP13, and AP14 has a diameter D4, which is about 20 μm.

Between the anode aperture AP11 and the anode aperture AP13, there is an interval having a width W61 along the first direction X, which is about 20 μm. Between the anode aperture AP12 and the anode aperture AP14, there is an interval having a width W62 along the first direction X, which is about 20 μm. Between the anode aperture AP11 and the anode aperture AP12, there is an interval having a width W71 along the second direction Y, which is about 20 μm. Between the anode aperture AP13 and the anode aperture AP14, there is an interval having a width W72 along the second direction Y, which is about 20 μm. The width W61, the width W62, the width W71, and the width W72 is equivalent to the width of the rib RB.

The light-shielding layer BM is disposed in the area indicated by the diagonal lines in the drawing. The light-shielding layer BM overlaps the rib RB in the entire area indicated by the diagonal lines in the drawing. The light-shielding layer BM has a plurality of apertures OP formed in positions that overlap the anode aperture AP11, the anode aperture AP12, the anode aperture AP13, and the anode aperture AP14, respectively. The apertures OP are formed into a circular shape. The diameter of each aperture OP is larger than the diameter D4 of the anode aperture AP11, the anode aperture AP12, the anode aperture AP13, and the anode aperture AP14.

The configurations of the subpixels SPX11, SPX12, SPX13, and SPX14 are identical to each other, and therefore they will be explained while focusing on the subpixel SPX11.

The anode aperture AP11 includes an edge EG4, which is an outer peripheral of the anode aperture AP11.

The plurality of lenses LS are formed to have sizes equal to each other and into a circular shape in plan view. The diameter D of each lens LS is, for example, about 12 μm.

In the example illustrated, four lenses LS41, LS42, LS43, and LS44 are disposed for the anode aperture AP11. The lenses LS41, LS42, LS43, and LS44 each overlap the anode aperture AP11, the edge EG4, and the rib RB, thereacross.

Note that in the example illustrated, part of each lens LS overlaps the light shielding layer BM.

As shown with reference to the lens LS41, the center O of the lens LS41 is located on an inner side of the edge EG4 of the anode aperture AP11. Similarly, the centers O of the other lenses LS are located on an inner side of the edges of the anode apertures AP11, AP12, AP13, and AP14, respectively. The center 0 of the lens LS41 is located on an inner side of the edge EG4 by a length L3 in the radial direction. The length L3 is, for example, about 3 μm.

In the second modified example as well, advantageous effects similar to those described above can be obtained.

### Third Modified Example

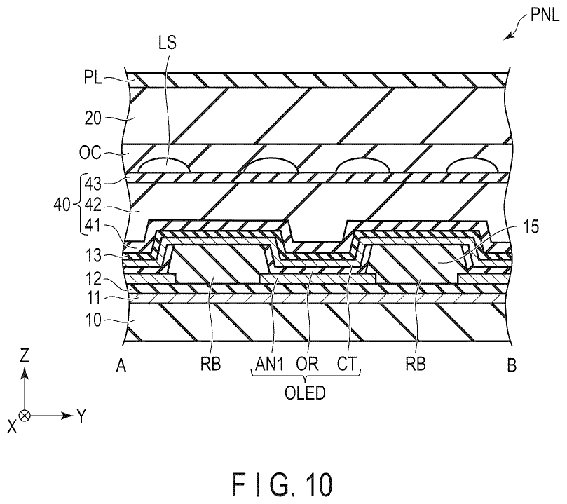

Next, with reference to FIG. 10, the configuration of the third modified example will be explained.

FIG. 10 is a cross-sectional view showing the third modified example of the display panel PNL.

The configuration shown in FIG. 10 is different from that shown in FIG. 3 in that the display panel PNL does not have a light shielding-layer BM and color filter layers CF.

The plurality of lenses LS are located on the sealing layer 40. The overcoat layer OC covers the plurality of lenses LS and the sealing layer 40. Further, the display panel PNL comprises a polarizer PL. The polarizer PL is located on the sealing substrate 20.

In this third modified example as well, advantageous effects similar to those described above can be obtained.

As explained above, according to this embodiment, it is possible to obtain a display device that can improve the light extraction efficiency.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
an insulating substrate;
an organic electroluminescence element located on the insulating substrate and comprising an anode electrode and an organic light emitting layer;
a rib located on the insulating substrate and including an anode aperture in a position that overlaps the anode electrode;
a sealing layer that seals the organic electroluminescence element and the rib between the insulating substrate and itself;
a first lens located on the sealing layer; and
an overcoat layer which covers the first lens, wherein
the first lens overlaps the anode aperture, an edge of the anode aperture, and the rib, thereacross.

2. The display device according to claim 1, further comprising:
a light-shielding layer located on the sealing layer; and
a color filter layer located on the light shielding-layer and the sealing layer, wherein
the first lens is located on the color filter layer.

3. The display device according to claim 1, wherein
the edge of the anode aperture includes a first edge and a second edge extending in a first direction, and a third edge and a fourth edge extending in a second direction which intersects the first direction, and
the first lens overlaps the anode aperture, the first edge and the third edge, and the rib, thereacross.

4. The display device according to claim 1, wherein
a center of the first lens is located on an inner side of the edge of the anode aperture.

5. The display device according to claim 2, wherein
the color filter layer includes a first color filter of a first color and a second color filter of a second color, which is a color different from the first color,
the first color filter and the second color filter are located adjacent to each other,
the first lens overlaps the first color filter without overlapping the second color filter.

6. The display device according to claim 1, wherein
the overcoat layer contains particles of either metal nanoparticles or hollow particles.

7. The display device according to claim 1, further comprising:
a second lens, a third lens, and a fourth lens, wherein
the second lens, the third lens, and the fourth lens each overlap the anode aperture, the edge of the anode aperture, and the rib, thereacross.

8. The display device according to claim 3, further comprising;
a second lens, a third lens, and a fourth lens, wherein
the second lens overlaps the anode aperture, the first edge and the fourth edge, and the rib, thereacross,
the third lens overlaps the anode aperture, the second edge and the third edge, and the rib, thereacross,
the fourth lens overlaps the anode aperture, the second edge and the fourth edge, and the rib, thereacross.

9. The display device according to claim 4, wherein
the first lens includes a sloping portion between the center of the first lens and an outer edge of the first lens, and
the sloping portion overlaps the rib.
